(19) United States
(12) Patent Application Publication
(10) Pub. No.: US 2022/0415860 A1
(43) Pub. Date: Dec. 29, 2022

(54) MICRO LIGHT EMITTING DIODE PANEL AND METHOD OF FABRICATING THE SAME

(71) Applicant: PlayNitride Display Co., Ltd., MiaoLi County (TW)

(72) Inventors: Kuan-Yung Liao, MiaoLi County (TW); Yun-Li Li, MiaoLi County (TW); Chih-Ling Wu, MiaoLi County (TW)

(73) Assignee: PlayNitride Display Co., Ltd., MiaoLi County (TW)

(21) Appl. No.: 17/701,678

(22) Filed: Mar. 23, 2022

Related U.S. Application Data
(60) Provisional application No. 63/215,996, filed on Jun. 29, 2021.

(30) Foreign Application Priority Data
Jul. 30, 2021 (TW) 110128003

(51) Int. Cl. H01L 25/075; H01L 21/683; H01L 33/00; H01L 33/62

(52) U.S. Cl. CPC H01L 25/0753; H01L 21/6835; H01L 33/0093; H01L 33/62; H01L 2933/0066; H01L 2221/68354; H01L 2221/68368

(57) ABSTRACT

A micro light emitting diode panel, including a circuit substrate, multiple transistor elements, and multiple micro light emitting diodes, is provided. The circuit substrate includes multiple signal lines, multiple bonding pads, and multiple thin film transistors. The bonding pads extend from at least part of the signal lines. The transistor elements are electrically bonded to a part of the bonding pads and are electrically connected to the thin film transistors. The micro light emitting diodes are electrically bonded to another part of the bonding pads and are electrically connected to the thin film transistors. The thin film transistors each have a first semiconductor pattern. The transistor elements each have a second semiconductor pattern. An electron mobility difference between the first semiconductor pattern and the second semiconductor pattern is greater than 30 cm²/V·s. A method of fabricating the micro light emitting diode panel is also provided.

### CROSS-REFERENCE TO RELATED APPLICATION

This application claims the priority benefit of U.S. Provisional Application No. 63/215,996, filed on Jun. 29, 2021 and Taiwan application serial no. 110128003, filed on Jul. 30, 2021. The entirety of each of the above-mentioned patent applications is hereby incorporated by reference herein and made a part of this specification.

### BACKGROUND

### Technical Field

The disclosure relates to a transfer technology of micro elements, and more particularly to a micro light emitting diode panel and a method of fabricating the same.

### Description of Related Art

In recent years, in the case where the cost of fabricating the organic light emitting diode (OLED) display panel is too high and the service life thereof cannot compete with the current mainstream displays, the micro light emitting diode (micro LED) display gradually attracts the investment attention of major technology companies. The micro light emitting diode display has optical performance equivalent to the organic light emitting diode display technology, such as high color saturation, fast response speed, and high contrast, and has the advantages of low energy consumption and long service life of material.

With the gradual increase in display size and resolution, the operational electrical properties such as electron mobility of the transistor element adopted by the display panel are bound to be improved. The low-temperature polycrystalline silicon thin film transistor (LTPS TFT) is widely applied to the small-size and high-resolution display panel due to the high electron mobility thereof. However, the leakage current of the LTPS TFT is greater when being turned off. In order to improve the power consumption efficiency of the display panel, an amorphous oxide semiconductor, a thin film transistor adopting an amorphous oxide semiconductor such as indium gallium zinc oxide (IGZO) semiconductor as an active layer is proposed. However, the electron mobility of such metal oxide semiconductor transistor cannot meet the application requirements of the high-resolution display panel.

### SUMMARY

The disclosure provides a micro light emitting diode panel, which has better operational electrical properties and reliability.

The disclosure provides a method of fabricating a micro light emitting diode panel, which has better process flexibility and greater product design margin.

The micro light emitting diode panel of the disclosure includes a circuit substrate, multiple transistor elements, and multiple micro light emitting diodes. The circuit substrate includes multiple signal lines, multiple bonding pads, and multiple thin film transistors. The signal lines are composed of multiple metal conductive layers and define multiple pixel areas. The bonding pads extend from a part of the signal lines. The thin film transistors are formed on the circuit substrate, and each have a first semiconductor pattern and multiple electrodes composed of the metal conductive layers. The electrodes are electrically connected to at least part of the bonding pads. The transistor elements are electrically bonded to a part of the bonding pads and are electrically connected to the thin film transistors. The micro light emitting diodes are electrically bonded to another part of the bonding pads and are electrically connected to the thin film transistors. The pixel areas are each provided with at least one thin film transistor, at least one transistor element, and at least one micro light emitting diode. The transistor elements each have a second semiconductor pattern. Electron mobility difference between the first semiconductor pattern and the second semiconductor pattern is greater than 30 cm²/V·s.

The method of fabricating a micro light emitting diode panel of the disclosure includes the following steps. Multiple signal lines, multiple thin film transistors, and multiple bonding pads are manufactured on a first substrate to form a circuit substrate having multiple pixel circuits. Multiple micro light emitting diodes are formed on a second substrate. Multiple transistor elements are formed on a third substrate or the second substrate. The third substrate, for example, may be a silicon-wafer substrate.

The micro light emitting diodes on the second substrate are transferred and bonded to a part of the bonding pads to electrically connect the thin film transistors of the circuit substrate. The transistor elements on the third substrate or second substrate are transferred and bonded to another part of the bonding pads to electrically connect the thin film transistors of the circuit substrate. The thin film transistors each have a first semiconductor pattern. The transistor elements each have a second semiconductor pattern. Electron mobility difference between the first semiconductor pattern and the second semiconductor pattern is greater than 30 cm/V·s.

Based on the above, in the micro light emitting diode panel and the method of fabricating the same according to an embodiment of the disclosure, the circuit substrate for driving the micro light emitting diodes is provided with two types of transistors. The two types of transistors have significantly different electron mobility and are respectively the thin film transistor and the transistor element. The thin film transistor is formed during the process of manufacturing the circuit substrate, and the transistor element is transferred and bonded onto the circuit substrate after being manufactured elsewhere. Therefore, the process flexibility and the design margin of the micro light emitting diode panel can be increased. In addition, the configuration of the two types of transistors with completely different properties can also improve the operational electrical properties of the pixel circuit, thereby increasing the reliability of the micro light emitting diode panel.

### BRIEF DESCRIPTION OF THE DRAWINGS

FIG. 1 is a schematic top-view of a micro light emitting diode panel according to a first embodiment of the disclosure.

FIG. 2 is a schematic cross-sectional view of the micro light emitting diode panel of FIG. 1.

FIG. 3 is a circuit diagram of a pixel circuit of FIG. 1.

FIG. 4A to FIG. 4F are cross-sectional views of a process of fabricating the micro light emitting diode panel of FIG. 1.

FIG. 5 is a schematic cross-sectional view of a micro light emitting diode panel according to a second embodiment of the disclosure.

FIG. 6 is a circuit diagram of a pixel circuit according to another embodiment of the disclosure.

FIG. 7 is a schematic cross-sectional view of a micro light emitting diode panel according to a third embodiment of the disclosure.

FIG. 8 is a circuit diagram of a pixel circuit of the micro light emitting diode panel of FIG. 7.

### DETAILED DESCRIPTION OF DISCLOSED EMBODIMENTS

In the drawings, the thickness of layers, films, panels, regions, etc., are exaggerated for clarity. It should be understood that when an element such as a layer, a film, a region, or a substrate is referred to as being “on” or “connected to” another element, the element may be directly on or connected to the another element, or there may be an intermediate element. In contrast, when an element is referred to as being “directly on” or “directly connected to” another element, there is no intermediate element. As used herein, “connection” may refer to physical and/or electrical connection. Furthermore, “electrical connection” may mean that there is another element between the two elements.

Reference will now be made in detail to the exemplary embodiments of the disclosure, and examples of the exemplary embodiments are illustrated in the accompanying drawings. Whenever possible, the same reference numerals are used in the drawings and description to indicate the same or similar parts.

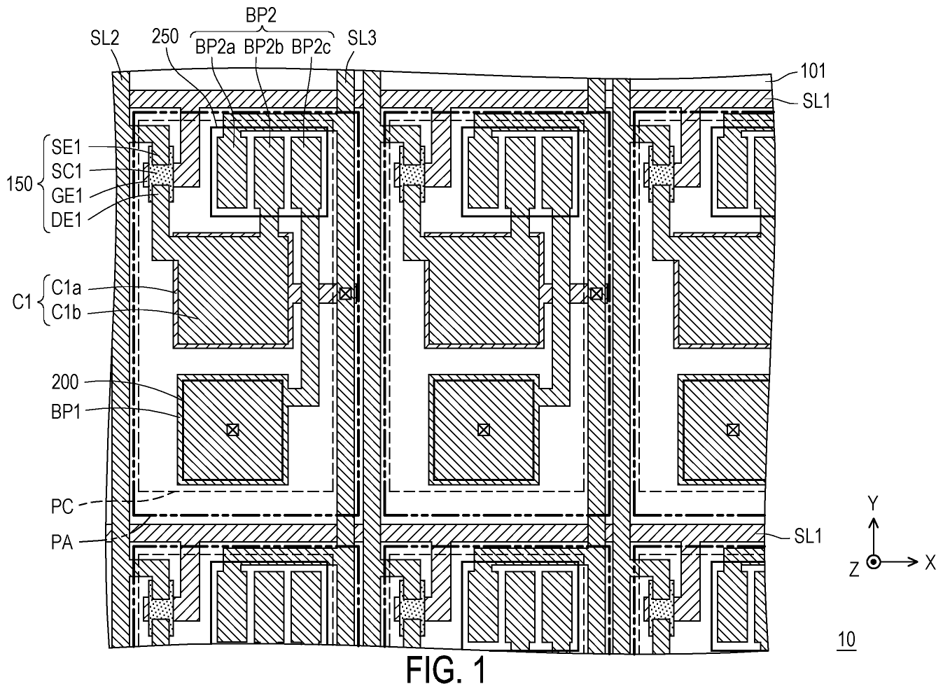

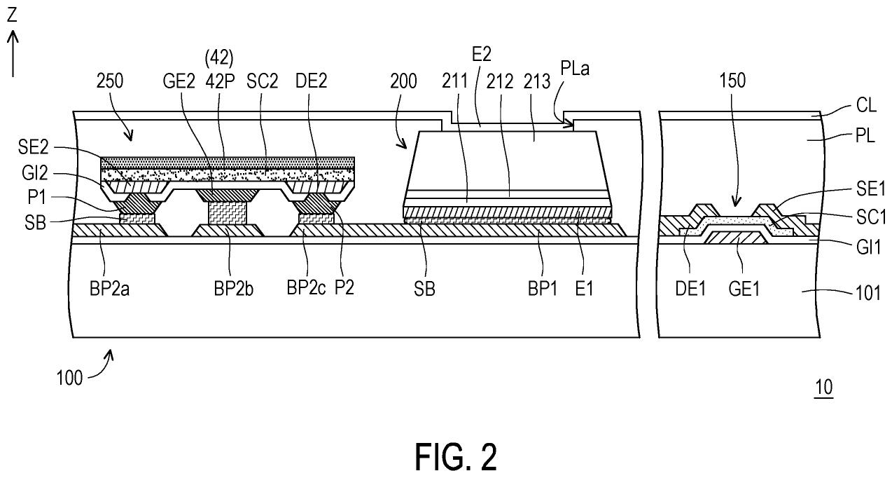

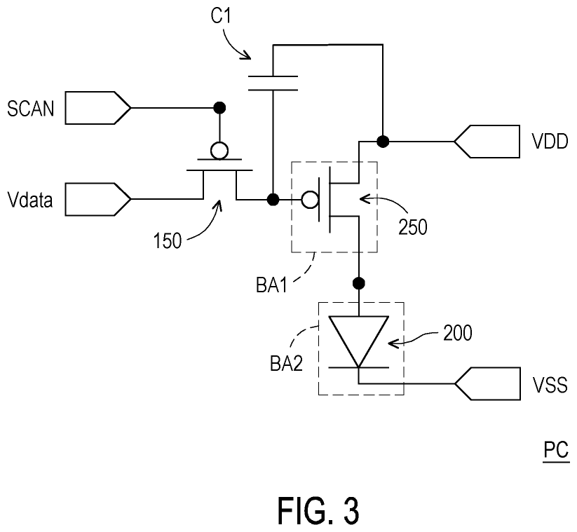

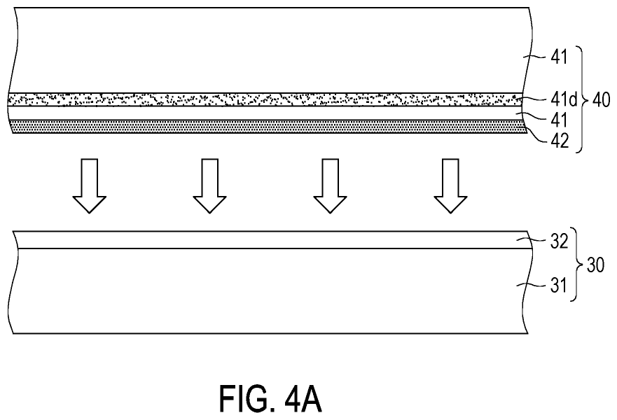

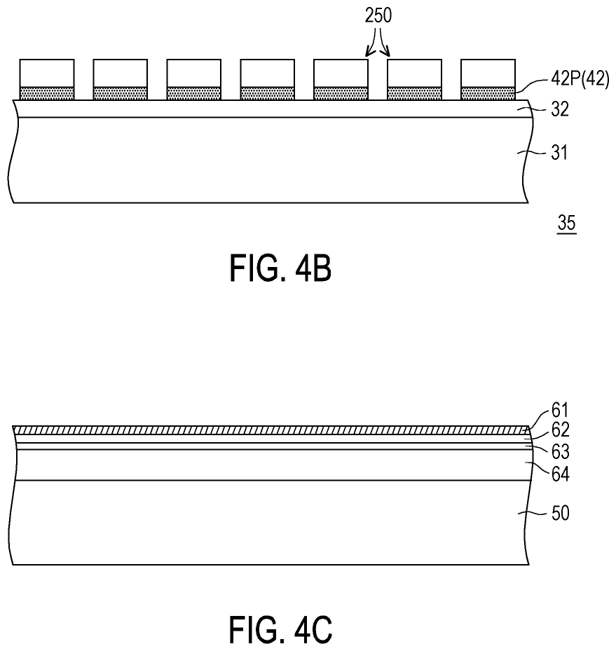

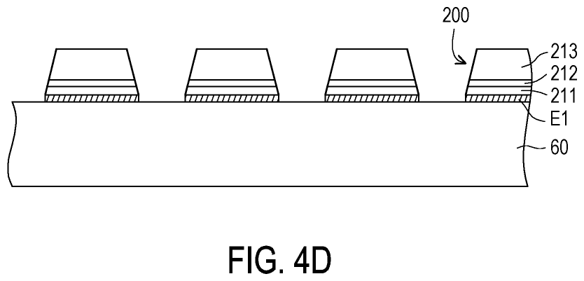

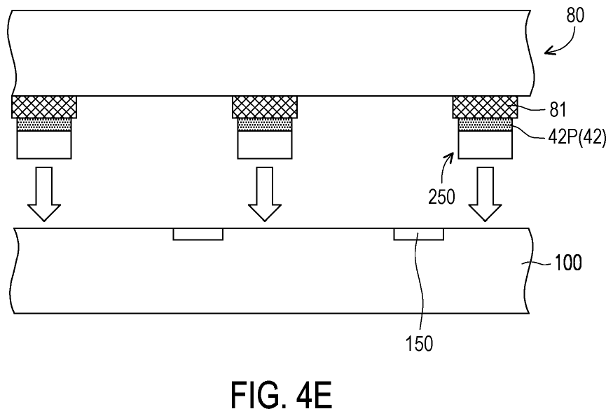

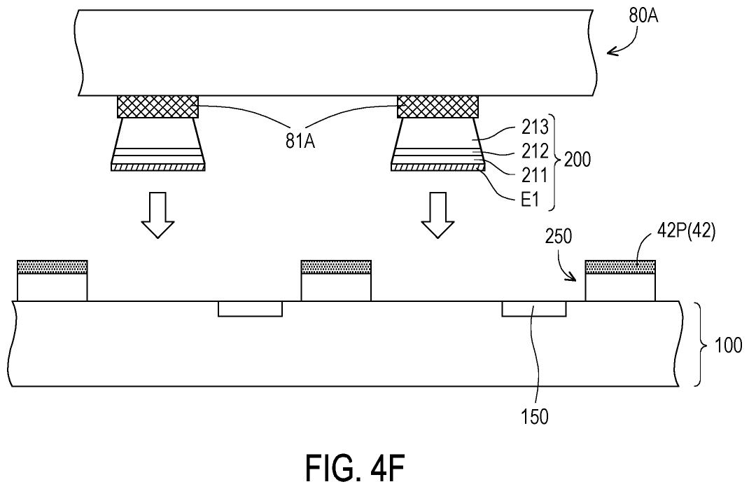

FIG. 1 is a schematic top-view of a micro light emitting diode panel according to a first embodiment of the disclosure. FIG. 2 is a schematic cross-sectional view of the micro light emitting diode panel of FIG. 1. FIG. 3 is a circuit diagram of a pixel circuit of FIG. 1. FIG. 4A to FIG. 4F are cross-sectional views of a process of fabricating the micro light emitting diode panel of FIG. 1.

Please refer to FIG. 1 and FIG. 2. A micro light emitting diode panel 10 includes a circuit substrate 100, multiple micro light emitting diodes 200, and multiple transistor elements 250. The micro light emitting diode 200 and the transistor element 250 are picked up by other carriers and bonded onto the circuit substrate 100 using a mass transfer process. The circuit substrate 100 includes multiple signal lines and multiple pixel circuits PC. The signal lines respectively extend toward at least one direction and define multiple pixel areas PA. The pixel circuits PC are respectively disposed corresponding to the pixel areas PA, that is, the pixel areas PA are each provided with at least one thin film transistor 150, at least one transistor element 250, and at least one micro light emitting diode 200.

For example, the circuit substrate 100 includes a substrate 101, multiple first signal lines SL1, multiple second signal lines SL2, multiple third signal lines SL3, and the thin film transistors 150. The first signal line SL1, the second signal line SL2, and the third signal line SL3 are composed of multiple stacked metal conductive layers. The first signal lines SL1 are arranged on the substrate 101 along a direction Y and extend in a direction X. The second signal lines SL2 and the third signal lines SL3 are alternately arranged on the substrate 101 along the direction X and extend in the direction Y. That is, the second signal line SL2 and the third signal line SL3 intersect at the first signal line SL1. In the embodiment, the first signal line SL1, the second signal line SL2, and the third signal line SL3 are, for example, respectively a scan line, a data line, and a power line, but not limited thereto.

On the other hand, the step of forming the thin film transistor 150 may include: sequentially forming a gate GE1, a gate insulating layer GI1, a semiconductor pattern SC1, a source SE1, and a drain DE1 on the substrate 101. In other words, the gate GE1 of the thin film transistor 150 may be selectively configured under the semiconductor pattern SC1 to form a bottom-gate thin film transistor (bottom-gate TFT), but the disclosure is not limited thereto. According to the thin film transistor of other embodiments, the gate GE1 may also be configured on the semiconductor pattern SC1 to form a top-gate thin film transistor (top-gate TFT).

In the embodiment, multiple electrodes such as the source SE1, the drain DE1, and the gate GE1 of the thin film transistor 150 are also formed by the metal conductive layers. For example, the source SE1, the drain DE1, and the second signal lines SL2 are the same film layer, and the gate GE1 and the first signal lines SL1 are the same film layer. In other words, the thin film transistor 150 is formed during the process of manufacturing the circuit substrate 100. In the embodiment, the material of the semiconductor pattern SC1 of the thin film transistor 150 may include metal oxide, amorphous silicon (a-Si), or low-temperature polycrystalline silicon (LTPS) semiconductor materials. That is, the thin film transistor 150 may be an indium gallium zinc oxide (IGZO) transistor, an a-Si TFT, or an LTPS TFT. More specifically, in an embodiment, electron mobility of a thin film transistor containing metal oxide may be between 10 cm²/V·s and 20 cm²/V·s. In another embodiment, electron mobility of a thin film transistor containing a-Si semiconductor material is lower than 10 cm²/V·s.

In particular, the micro light emitting diode panel 10 is manufactured using mass transfer technology. For example, the micro light emitting diodes 200 and the transistor elements 250 manufactured elsewhere in advance are transferred and bonded to multiple bonding areas (for example, a bonding area BA1 and a bonding area BA2 as shown in FIG. 3) of the circuit substrate 100. Therefore, the circuit substrate 100 further includes multiple bonding pads BP1 for bonding the micro light emitting diodes 200 and multiple bonding pads BP2 for bonding the transistor elements 250. The bonding pads are respectively connected to at least part of the signal lines. In the embodiment, the bonding pads are formed by the extension of part of the signal lines. The thin film transistors 150 are electrically connected to at least part of the bonding pads and are electrically connected to the corresponding signal lines.

For example, in the embodiment, the number of the bonding pads BP2 for bonding the transistor element 250 is three, which are respectively a bonding pad BP2a, a bonding pad BP2b, and a bonding pad BP2c. The bonding pad BP2a is electrically connected to the third signal line SL3. The bonding pad BP2b is electrically connected to a capacitance electrode C1a of a storage capacitor C1. The number of the bonding pad BP1 for bonding the micro light emitting diode 200 is one. The bonding pad BP1 is electrically coupled to the third signal line SL3 via the transistor element 250.

The micro light emitting diode 200 includes an epitaxial structure, a first electrode E1, and a second electrode E2. In the embodiment, the first electrode E1 and the second electrode E2 are respectively disposed on two opposite sides of the epitaxial structure, and the micro light emitting diode 200 is electrically connected to the circuit substrate 100 via a bonding relationship between the first electrode E1 and the bonding pad BP1. That is, the micro light emitting diode 200 of the embodiment is a vertical type micro light emitting element, but not limited thereto. Furthermore, the epitaxial structure may include a first type semiconductor layer 211, a light emitting layer 212, and a second type semiconductor layer 213, and the first electrode E1 and the second electrode E2 are respectively electrically connected to the first type semiconductor layer 211 and the second type semiconductor layer 213. In the embodiment, the first type semiconductor layer 211 and the second type semiconductor layer 213 may respectively be a P-type semiconductor and an N-type semiconductor, and the light emitting layer 212 may have a multiple quantum well (MQW) structure, but not limited thereto.

It should be noted that in the embodiment, the first type semiconductor layer 211 and the second type semiconductor layer 213 may have different thicknesses in a normal direction (for example, a direction Z) of the substrate 101. For example, the vertical thickness of the second type semiconductor layer 213 is greater than the vertical thickness of the first type semiconductor layer 211. In other words, the light emitting layer 212 of the micro light emitting diode 200 may be located in a region (as shown in FIG. 2) where the epitaxial structure is closer to the first electrode E1, but not limited thereto. In other embodiments, the first type semiconductor layer 211 and the second type semiconductor layer 213 have substantially the same thickness in the direction Z. That is, the light emitting layer 212 may be selectively located in a middle region of the epitaxial structure.

The micro light emitting diode panel 10 further includes a planarization layer PL and a transparent conductive layer CL. The planarization layer PL covers the transistor element 250, the micro light emitting diode 200, and a portion of the circuit substrate 100, and has multiple openings PLa overlapping with the micro light emitting diodes 200. The transparent conductive layer CL covers the planarization layer PL and extends into the openings PLa to form the second electrode E2 in electrical contact with the micro light emitting diodes 200. In other words, the second electrode E2 of the embodiment is implemented in the form of a common electrode.

Furthermore, the transistor element 250 that is also bonded to the circuit substrate 100 via the mass transfer process may have a source SE2, a drain DE2, a gate GE2, and a semiconductor pattern SC2. The source SE2 and the drain DE2 are electrically connected to the semiconductor pattern SC2. It should be noted that the source SE2, the drain DE2, and the gate GE2 may be located between the semiconductor pattern SC2 and the circuit substrate 100, but not limited thereto. In the embodiment, the transistor element 250 may further have a pad P1 and a pad P2, and the pad P1 and the pad P2 penetrate a gate insulating layer GI2 of the transistor element 250 to respectively electrically connect the source SE2 and the drain DE2. In the embodiment, the transistor element 250 is electrically connected to the circuit substrate 100 via bonding relationships of the pad P1, the pad P2, and the gate GE2 respectively with the bonding pad BP2a, the bonding pad BP2b, and the bonding pad BP2c, but not limited thereto.

In particular, since the material of the semiconductor pattern SC2 of the transistor element 250 may include polycrystalline silicon, single crystalline silicon, or other materials with high electron mobility, the transistor element 250 may have higher electron mobility, such as a transistor element with electron mobility higher than 100 cm²/V·s, which helps to improve the operational electrical properties of the micro light emitting diode panel 10 during high frequency driving. However, the disclosure is not limited thereto. According to other embodiments, the material of the semiconductor pattern SC2 may also include LTPS. In other words, the transistor element 250 may also be a LTPS TFT or a micro silicon (micro-Si) TFT. More specifically, in an embodiment, electron mobility of a transistor element containing LTPS may be higher than 50 cm²/V·s.

Please refer to FIG. 3 at the same time. In the embodiment, the pixel circuit PC of the circuit substrate 100 has a 2T1C architecture, such as containing the transistor element 250 bonded onto the substrate 101 via transfer and the thin film transistor 150 and the storage capacitor C1 formed on the substrate 101. A control terminal (for example, a gate GE2 terminal) of the transistor element 250 is electrically connected to a capacitance electrode C1b of the storage capacitor C1. A first terminal (for example, a source SE2 terminal) of the transistor element 250 is electrically connected to the third signal line SL3 to receive a system high voltage VDD. A second terminal (for example, a drain DE2 terminal) of the transistor element 250 is electrically connected to an anode (for example, the first electrode E1) of the micro light emitting diode 200. A cathode (for example, the second electrode E2) of the micro light emitting diode 200 is connected to a system low voltage VSS or ground. A control terminal (for example, a gate GE1 terminal) of the thin film transistor 150 is electrically connected to the first signal line SL1 to receive a gate drive signal SCAN. A first terminal (for example, a source SE1 terminal) of the thin film transistor 150 is electrically connected to the second signal line SL2 to receive image data Vdata. A second terminal (for example, a drain DE1 terminal) of the thin film transistor 150 is electrically connected to the capacitance electrode C1b of the storage capacitor C1 and the control terminal of the transistor element 250.

For example, in a display period, the driving of the pixel circuit PC may be divided into two stages, which are respectively a data writing stage and a light emitting stage. During the data writing stage, the thin film transistor 150 is turned on, so that the image data Vdata can be written into the storage capacitor C1. After writing the image data Vdata, the thin film transistor 150 is turned off, and the transistor element 250 adjusts the magnitude of the driving current flowing through the micro light emitting diode 200 according to a write voltage value of the storage capacitor C1, so that the micro light emitting diode 200 is driven to emit light having corresponding light intensity. During the display period, different pixel circuits PC are sequentially activated to emit image light, and the display effect is achieved through the persistence of human vision.

Since the thin film transistor 150 is directly manufactured on the substrate 101 using a semiconductor process and has a relatively uniform electrical performance, the thin film transistor 150 may be used as a switch circuit for controlling the writing of the image data Vdata into the storage capacitor C1 in the pixel circuit PC. On the other hand, in the embodiment, although the electron mobility of the thin film transistor 150 is lower than the electron mobility of the transistor element 250, the leakage current of the thin film transistor 150 when being turned off is lower than the leakage current of the transistor element 250. In addition, the transistor element 250 may be used as a drive transistor for controlling the magnitude of the current flowing through the micro light emitting diode 200 in the pixel circuit PC. For example, the electron mobility difference between the semiconductor pattern SC1 of the thin film transistor 150 and the semiconductor pattern SC2 of the transistor element 250 may be greater than 30 cm²/V·s.

In other words, the transistor element 250 has high frequency operation properties, and the thin film transistor 150 has stable current control properties. Therefore, through the combined use of the two types of transistors, in addition to increasing the design margin of the pixel circuit PC, the operational electrical properties of the pixel circuit PC can also be improved, thereby increasing the reliability of the micro light emitting diode panel 10. From another point of view, since the electrical properties of the two types of transistors are fairly different, the required process conditions are also different. Therefore, one type of the transistors is manufactured elsewhere and then transferred, which can increase the overall process flexibility and ensure the yield and display quality of the display panel.

For example, in the embodiment, the transistor element 250 is a single crystalline silicon or polycrystalline silicon thin film transistor, and the thin film transistor 150 is a metal oxide transistor or an a-Si TFT. Since the process temperature of the single crystalline silicon or polycrystalline silicon thin film transistor is higher than the process temperature of the metal oxide transistor or the a-Si TFT, the transistor element 250 is manufactured elsewhere by a high-temperature process first, which can prevent other elements (for example, the thin film transistor 150) on the circuit substrate 100 from degrading during the high-temperature process and affecting the electrical properties. In other words, the overall production yield can be ensured while improving the operational electrical properties of the pixel circuit PC.

The process of fabricating the micro light emitting diode panel 10 will be exemplarily described below. Please refer to FIG. 1 and FIG. 2. Firstly, the first signal lines SL1, the second signal lines SL2, the third signal lines SL3, the thin film transistors 150, the bonding pads BP1, and the bonding pads BP2 are manufactured on the substrate 101 to form the circuit substrate 100 having the pixel circuits PC. The thin film transistors 150 are electrically connected to the first signal lines SL1 and the second signal lines SL2, and a part of the bonding pads BP2 are electrically connected to the third signal lines SL3.

The transistor elements 250 are manufactured on another substrate. Please refer to FIG. 4A and FIG. 4B. Firstly, a semiconductor material substrate 35 is formed. In detail, a sacrificial layer 32 is formed on a carrier 31. A stacked structure including, for example, a single crystalline silicon material layer 41, a hydrogen-doped crystalline silicon material layer 41d, and an inorganic insulating layer 42 is formed on another silicon wafer 40. That is, the silicon wafer 40 may be a multilayer stacked structure with multiple semiconductor material layers and the inorganic insulating layer 42. In particular, the hydrogen-doped crystalline silicon material layer 41d may be selectively located in a region of the single crystalline silicon material layer 41 closer to the inorganic insulating layer 42. In other words, a portion of the single crystalline silicon material layer 41 located between the hydrogen-doped crystalline silicon material layer 41d and the inorganic insulating layer 42 may form a single crystalline silicon thin film.

For example, the semiconductor material substrate 35 of the embodiment is formed by bonding the silicon wafer 40 onto an epitaxial substrate 30. More specifically, during the process of forming the semiconductor material substrate 35, the silicon wafer 40 is connected to the epitaxial substrate 30 through a bonding relationship between the inorganic insulating layer 42 and the sacrificial layer 32. After bonding the silicon wafer 40 and the epitaxial substrate 30, a high-temperature process may be performed to blister and peel the hydrogen-doped crystalline silicon material layer 41d, so that two portions of the single crystalline silicon material layer 41 located on two opposite sides of the hydrogen-doped crystalline silicon material layer 41d are separated from each other. Then, a portion of the single crystalline silicon material layer 41 still connected to the inorganic insulating layer 42 may be further subjected to a chemical mechanical polishing (CMP) process to form a semiconductor material layer of the semiconductor material substrate 35. In more detail, the thickness of the single crystalline silicon material layer 41 may be initially controlled by controlling a depth position of the hydrogen-doped crystalline silicon material layer 41d, and the thickness of the semiconductor material layer may be then more precisely controlled by chemical mechanical polishing. However, the disclosure is not limited thereto. According to other embodiments, the semiconductor material substrate may also form the semiconductor material layer on the epitaxial substrate through epitaxial film formation.

In the embodiment, the carrier 31 is, for example, a sapphire substrate, a glass substrate, a silicon wafer substrate, a silicon carbide substrate, or a polymer substrate, but the disclosure is not limited thereto. In the embodiment, the material of the sacrificial layer 32 may include gallium nitride (GaN), silicon oxide, or silicon nitride. The material of the inorganic insulating layer 42 includes silicon oxide (SiO₂), silicon nitride (SiNₓ), silicon oxynitride (SiOₓN_{y}, where x>y), silicon oxynitride (SiNₓO_{y}, where x>y), or other suitable inorganic insulating materials.

Next, the transistor elements 250 are formed on the semiconductor material substrate 35, as shown in FIG. 4B. Please refer to FIG. 2 at the same time. For example, the step of forming the transistor element 250 may include patterning the semiconductor material layer and the inorganic insulating layer 42 to form the semiconductor patterns SC2 and multiple insulating patterns 42P, forming the source SE2 and the drain DE2, forming the gate insulating layer GI2, and forming the gate GE2. Based on the consideration of conductivity, the materials of the source SE2, the drain DE2, and the gate GE2 are generally metallic materials. However, the disclosure is not limited thereto. According to other embodiments, the source SE2, the drain DE2, and the gate GE2 may also use other conductive materials, such as alloys, nitrides of metallic materials, oxides of metallic materials, oxynitrides of metallic materials, other suitable materials, or stacked layers of metallic materials and other conductive materials.

In the embodiment, since the insulating pattern 42P and the semiconductor pattern SC2 are formed during the same lithographic etching process, the insulating pattern 42P may be aligned with the semiconductor pattern SC2 in a normal direction of the carrier 31. That is, the insulating pattern 42P may completely overlap with the semiconductor pattern SC2. However, the disclosure is not limited thereto. According to other embodiments, the inorganic insulating layer 42 may also be optionally subjected to the lithographic etching process simultaneously with the gate insulating layer GI2 to form multiple insulating patterns. Furthermore, the step of forming the transistor element 250 may further include forming multiple pads, such as the pad P1 and the pad P2. The pad P1 and the pad P2 penetrate the gate insulating layer GI2 to respectively electrically connect the source SE2 and the drain DE2, but not limited thereto, and the pad may also be manufactured during a subsequent transfer process. In the embodiment, the materials of the pad P1, the pad P2, and the gate GE2 may be selectively the same. In other words, the pad P1, the pad P2, and the gate GE2 may belong to the same film layer, but not limited thereto.

The method of fabricating the micro light emitting diode panel 10 further includes forming the micro light emitting diodes 200 on another substrate. Please refer to FIG. 4C and FIG. 4D. Firstly, a second type semiconductor material layer 64, a light emitting material layer 63, an epitaxial structure thin film of a first type semiconductor material layer 62, and an electrode layer 61 are epitaxially formed on an epitaxial substrate 50. Then, transferring the second type semiconductor material layer 64, a light emitting material layer 63, the first type semiconductor material layer 62, and an electrode layer 61 from the epitaxial substrate 50 to a wafer substrate 60.

After transferring the semiconductor material layers and the electrode layer, an etching step (that is, a patterning process) is performed on the second type semiconductor material layer, the light emitting material layer, the first type semiconductor material layer, and the electrode layer to form multiple epitaxial structures and the first electrodes E1 of the micro light emitting diodes 200. The epitaxial structure is formed by stacking the first type semiconductor layer 211 patterned from the first type semiconductor material layer 62, the light emitting layer 212 patterned from the light emitting material layer 63, and the second type semiconductor layer 213 patterned from the second type semiconductor material layer 64.

Please refer to FIG. 4E to FIG. 4F. After forming the transistor elements 250, the transistor elements 250 may be selectively transferred from the carrier 31 to a temporary substrate, and the transistor elements 250 are then transferred and bonded to the circuit substrate 100 using the temporary substrate, but not limited thereto. In other embodiments, the transistor elements 250 may also be directly transferred to the circuit substrate 100. In the embodiment, the transistor elements 250 are transposed onto the circuit substrate 100 after two transfer processes.

In detail, during the process of transferring the transistor element 250, a carrier structure (not shown) having an adhesive layer is used to temporarily fix the transistor element 250 to the carrier structure first. During the process, the sacrificial layer 32 may be removed, so that the transistor elements 250 are separated from the carrier 31. For example, laser lift off (LLO) may be adopted to remove the sacrificial layer 32, but the disclosure is not limited thereto. In other embodiments, a fixing structure may also be formed on the carrier 31, and the fixing structure is suitable for temporarily fixing the transistor elements 250 onto the carrier 31. During a lifting process after the carrier structure is adhered with the transistor elements 250, the fixing structure may be easily destroyed, so that the transistor elements 250 are separated from the carrier 31. For example, the material of the adhesive layer may include a viscous material. The viscous material is, for example, an organic material (for example, benzocyclobutene, phenol formaldehyde resin, epoxy resin, polyisoprene rubber, or a combination thereof), an inorganic material (for example, silicon oxide, silicon nitride, silicon oxynitride, or a combination thereof), or a thermally degraded material (for example, a cold brittle material, a hot melt material, a photoresist material, or a combination thereof). The adhesive layer may transpose (transfer and place) the transistor elements 250 through an adhesive relationship with the transistor elements 250, but the disclosure is not limited thereto.

Then, a transfer part 81 of a selectively transferable carrier structure 80 is used to extract the transistor elements 250 on the carrier structure, and the transistor elements 250 are fixed onto the carrier structure 80 through an attachment relationship between the insulating pattern 42P and the transfer part 81 (as shown in FIG. 4E). The carrier structure 80 may selectively flip and transpose the transistor elements 250 onto the circuit substrate 100 (as shown in FIG. 4F). At this time, different from the configuration of the transistor elements 250 and the insulating pattern 42P on the carrier 31 (as shown in FIG. 4B), the transistor elements 250 may be selectively located between the circuit substrate 100 and the insulating pattern 42P, but not limited thereto. It is worth mentioning that since one side of the transistor element 250 away from the circuit substrate 100 is provided with the insulating pattern 42P, during a subsequent process, there is no need to form an additional insulating layer to prevent other conductive film layers from being electrically short-circuited with the transistor element 250, which helps to lower the production cost. In other embodiments, the extraction manner used in the transposition technology of the transistor elements 250 may also include an electrostatic force, a Van Der Waals force, and other manners.

Please refer to FIG. 4D and FIG. 4F. After forming the micro light emitting diodes 200, the micro light emitting diodes 200 may be transferred and bonded to the circuit substrate 100 from the wafer substrate 60. In the embodiment, the micro light emitting diodes 200 and the transistor elements 250 may be electrically bonded to the bonding pads of the circuit substrate 100 via multiple solder bumps SB. The solder bump SB is, for example, manufactured using a conductive material such as indium and tin, but not limited thereto.

For example, the micro light emitting diodes 200 may be transposed to a region between two adjacent transistor elements 250 on the circuit substrate 100 through a transfer part 81A of a carrier structure 80A. In other words, the transistor elements 250 and the micro light emitting diodes 200 may be alternately arranged on the circuit substrate 100 along an extension direction of the second signal line SL2 (as shown in FIG. 1). According to other embodiments, more than two micro light emitting diodes 200 may be disposed between two adjacent transistor elements 250. It should be noted that the disclosure does not limit the configuration of multiple transfer parts on the carrier structure with the content disclosed in the drawing. In other embodiments, the configuration (for example, arrangement period or spacing) of the transfer parts on the carrier structure may also be adjusted according to actual product design and process requirements.

Please refer to FIG. 2. After transposing the micro light emitting diodes 200 and the transistor elements 250 to the circuit substrate 100, the planarization layer PL is formed to cover the transistor elements 250 and the micro light emitting diodes 200. The planarization layer PL has the openings PLa overlapping with the micro light emitting diodes 200. In the embodiment, the material of the planarization layer PL may include an inorganic material (for example, silicon oxide, silicon nitride, silicon oxynitride, other suitable materials, or a stacked layer of at least two of the above materials), an organic material, other suitable materials, or a combination of the above. Next, the transparent conductive layer CL is formed on the planarization layer PL. The transparent conductive layer CL covers the planarization layer PL and extends into the openings PLa of the planarization layer PL to electrically connect the micro light emitting diodes 200. At this point, the micro light emitting diode panel 10 of the embodiment is completed.

In particular, during the process of fabricating the micro light emitting diode panel 10 of the embodiment, the components adopting the transfer technology are illustrated by taking the transistor elements 250 and the micro light emitting diodes 200 as examples, but the disclosure is limited thereto. According to other unshown embodiments, the micro light emitting diode panel may further include a micro integrated circuit, a micro sensor, a microchip having a circuit, or other micro semiconductors that may be controlled to execute predetermined electronic functions, and the micro elements may also be transferred through the above transposition manner.

Other embodiments will be listed below to describe the disclosure in detail. The same components will be marked with the same reference numerals, and the description of the same technical content will be omitted. For the omitted parts, please refer to the above embodiment, which will not be repeated.

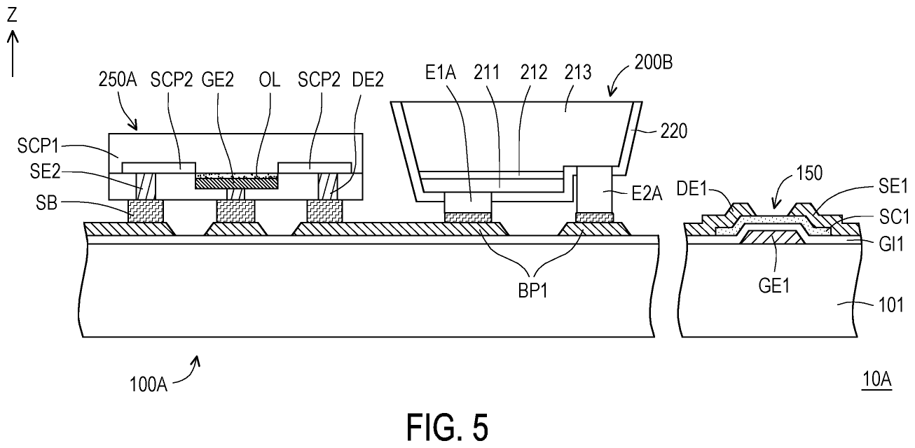

FIG. 5 is a schematic cross-sectional view of a micro light emitting diode panel according to a second embodiment of the disclosure. Please refer to FIG. 5. The difference between a micro light emitting diode panel 10A of the embodiment and the micro light emitting diode panel 10 of FIG. 2 is that: the configurations of the transistor element and the micro light emitting diode are different. Specifically, a transistor element 250A of the micro light emitting diode panel 10A has, for example, a structure of a metal oxide semiconductor field effect transistor (MOSFET). For example, the transistor element 250A may include semiconductor patterns SCP1 and SCP2, the source SE2, the drain DE2, the gate GE2, and an oxide layer OL. The semiconductor pattern SCP2 is disposed corresponding to and is respectively electrically connected the source SE2 and the drain DE2, and is located on two opposite sides of the gate GE2 and the oxide layer OL. The oxide layer OL is disposed between the semiconductor patterns SCP1 and gate GE2.

In the embodiment, the materials of the semiconductor patterns SCP1 and SCP2 are, for example, single crystalline silicon implanted by ions and doped with different elements to form transistors with different electrical properties. In other words, the transistor element 250A may be an N-type metal oxide semiconductor (NMOS) transistor, but not limited thereto. In other embodiments, the transistor element 250A may also be a P-type semiconductor or the transistor element 250A may be a complementary metal oxide semiconductor (CMOS) transistor element formed by a collection of multiple transistor elements.

On the other hand, a micro light emitting diode 200B of the micro light emitting diode panel 10A of the embodiment has, for example, a flip-chip type structure. In detail, a first electrode E1A and a second electrode E2A of the micro light emitting diode 200B of the embodiment are formed on the same side of the epitaxial structure and are bonded onto different bonding pads BP1 on the circuit substrate 100. The first electrode E1A and the second electrode E2A penetrate an insulating layer 220 covering the epitaxial structure to respectively electrically connect the first type semiconductor layer 211 and the second type semiconductor layer 213 of the epitaxial structure.

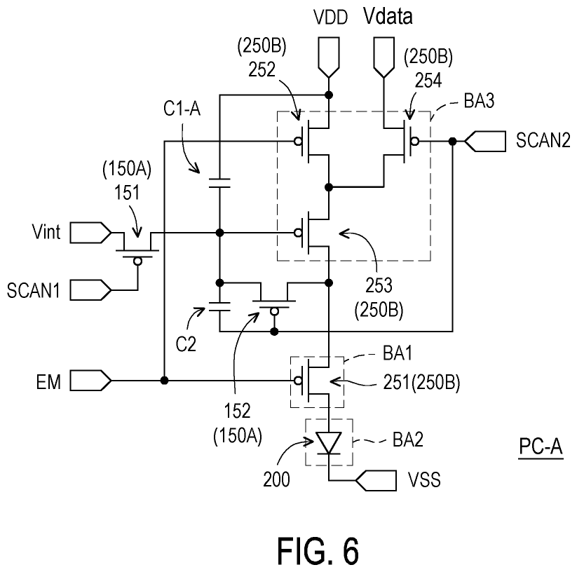

FIG. 6 is a circuit diagram of a pixel circuit according to another embodiment of the disclosure. Please refer to FIG. 6. The difference between a pixel circuit PC-A of the embodiment and the pixel circuit PC of FIG. 3 is that: the pixel circuit PC-A has a 6T2C architecture. For example, in the embodiment, the pixel circuit PC-A may include two thin film transistors 150A, four transistor elements 250B, a storage capacitor C1-A, and a compensation capacitor C2. Four transistor elements 251 to 254 and the micro light emitting diode 200 are transferred and bonded to multiple bonding areas such as the bonding area BA1, the bonding area BA2, and a bonding area BA3 of the circuit substrate after being manufactured elsewhere.

In detail, a control terminal of a thin film transistor 151 receives a gate drive signal SCAN1. A first terminal of the thin film transistor 151 receives a reset signal Vint. A second terminal of the thin film transistor 151 is coupled to a control terminal of the transistor element 253, a first terminal of the storage capacitor C1-A, a first terminal of the compensation capacitor C2, and a first terminal of a thin film transistor 152. A second terminal of the storage capacitor C1-A and a first terminal of the transistor element 252 are coupled to the system high voltage VDD. A second terminal of the transistor element 252 is coupled to a first terminal of the transistor element 253 and a second terminal of the transistor element 254. A second terminal of the transistor element 253 is coupled to a second terminal of the thin film transistor 152 and a first terminal of the transistor element 251. A first terminal of the transistor element 254 receives the image data Vdata. A control terminal of the transistor element 254 receives a gate drive signal SCAN2. A control terminal of the transistor element 251 and a control terminal of the transistor element 252 receive a light emitting signal EM. A second terminal of the transistor element 251 is coupled to a first terminal of the micro light emitting diode 200. A control terminal of the thin film transistor 152 is coupled to a second terminal of the compensation capacitor C2 and a control terminal of the transistor element 254. A second terminal of the micro light emitting diode 200 is coupled to the system low voltage VSS.

In the embodiment, the operation flow of the pixel circuit PC-A may be divided into three stages, which are respectively a reset stage, the data writing stage, and the light emitting stage. The transistor element 252, the transistor element 253, the transistor element 254, and the storage capacitor C1-A are a driving unit of the pixel circuit PC-A and are configured to write the image data Vdata into the storage capacitor C1-A during the data writing stage and control the driving current flowing through the micro light emitting diode 200 during the light emitting stage. The transistor element 251 is a light emission control unit of the pixel circuit PC-A and is configured to control the driving current from the driving unit to the micro light emitting diode 200 during the light emitting stage.

The thin film transistor 151 is a reset unit of the pixel circuit PC-A and is configured to initialize the voltage of the first terminal of the storage capacitor C1-A of the driving unit during the reset stage. The compensation capacitor C2 and the thin film transistor 152 are a compensation unit of the pixel circuit PC-A and are configured to adjust the driving current flowing through the micro light emitting diode 200 during the light emitting stage. The driving unit is coupled between the reset unit and the light emission control unit, and the compensation unit is coupled between the light emission control unit and the driving unit.

In particular, in order to meet the requirements of the operational electrical properties of different units in the pixel circuit PC-A, the types of transistors used in each circuit unit may be different. For example, in the embodiment, switch elements of the reset unit and the compensation unit may be the thin film transistor 150A with lower electron mobility but lower leakage current, and switch elements of the driving unit and the light emission control unit may be the transistor element 250B with higher electron mobility but higher leakage current, but not limited thereto.

Through the combined use of the two types of transistors, in addition to increasing the design margin of the pixel circuit PC-A, the operational electrical properties of the pixel circuit PC-A can also be improved, thereby increasing the reliability of the micro light emitting diode panel. From another point of view, since the electrical properties of the two types of transistors are fairly different, the required process conditions are also different. Therefore, one type of the transistors is manufactured elsewhere and then transferred, which can increase the overall process flexibility. In other words, the overall production yield can be ensured while improving the operational electrical properties of the pixel circuit PC-A.

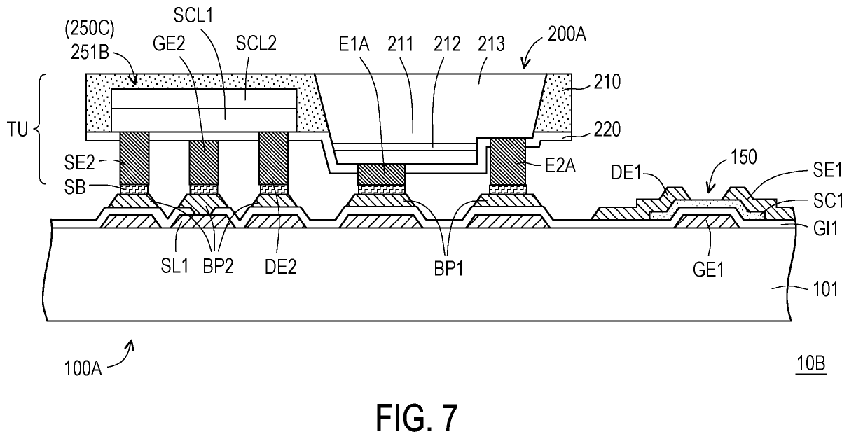

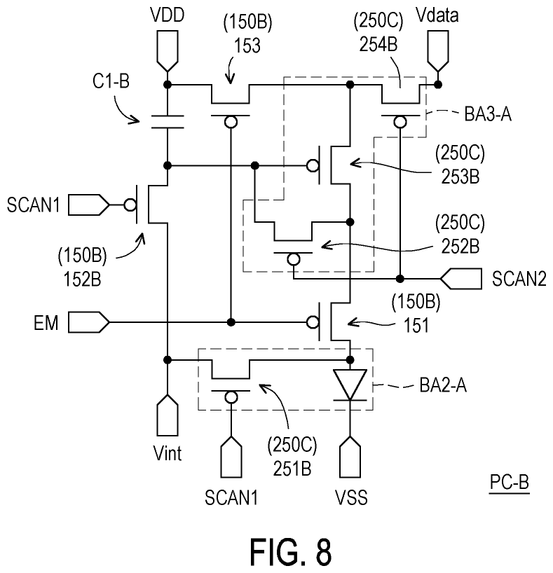

FIG. 7 is a schematic cross-sectional view of a micro light emitting diode panel according to a third embodiment of the disclosure. FIG. 8 is a circuit diagram of a pixel circuit of the micro light emitting diode panel of FIG. 7. Please refer to FIG. 7. The main difference between a micro light emitting diode panel 10B of the embodiment and the micro light emitting diode panel 10 of FIG. 2 is that: a micro light emitting diode 200A and a transistor element 251B of the micro light emitting diode panel 10B are simultaneously bonded onto the circuit substrate 100 during the transfer process.

In the embodiment, a part of transistor elements 250C and the micro light emitting diode 200A may be manufactured on the same semiconductor substrate 210 to form a transfer unit TU. For example, the method of fabricating the micro light emitting diode panel 10B may further include forming the semiconductor substrate 210, the transistor element 250C, and the micro light emitting diode 200A on the same epitaxial substrate. The transistor element 250C and the micro light emitting diode 200A are formed in the semiconductor substrate 210, and the step of transferring and bonding the transistor element 250C and the micro light emitting diode 200A includes the transfer of the semiconductor substrate 210.

It should be noted that the first electrode E1A and the second electrode E2A of the micro light emitting diode 200A are located on the same side of the epitaxial structure. More specifically, the micro light emitting diode 200A of the embodiment is, for example, a flip-chip type micro light emitting element. The transistor element 250C has a first type semiconductor layer SCL1, a second type semiconductor layer SCL2, the source SE2, the drain DE2, and the gate GE2. The source SE2, the drain DE2, and the gate GE2 are located on one side of the first type semiconductor layer SCL1 away from the second type semiconductor layer SCL2.

The transfer unit TU is also provided with the insulating layer 220 covering the semiconductor substrate 210, the transistor element 250C, and the micro light emitting diode 200A. The first electrode E1A and the second electrode E2A of the micro light emitting diode 200A penetrate the insulating layer 220 to respectively electrically connect the first type semiconductor layer 211 and the second type semiconductor layer 213. The source SE2 and the drain DE2 of the transistor element 250C penetrate the insulating layer 220 to electrically connect two different regions of the first type semiconductor layer SCL1.

For example, the first type semiconductor layer SCL1 and the second type semiconductor layer SCL2 are respectively an AlGaN layer and a GaN layer, and a heterojunction of the two semiconductor layers can form two-dimensional electron gas (2DEG). In 2DEG, electrons may have a high mobility of, for example, 400 cm²/V·s to 800 cm²/V·s. In other words, the transistor element 250C of the embodiment is a high electron mobility transistor (HEMT) and is suitable for high frequency and high power applications. Since the thin film transistor 150B of the embodiment is similar to the thin film transistor 150 of FIG. 2, for detailed description, please refer to the relevant paragraphs of the above embodiment, which will not be repeated.

Please also refer to FIG. 8. In the embodiment, a pixel circuit PC-B of the micro light emitting diode panel 10B has a 7T1C architecture. For example, the pixel circuit PC-B may include three thin film transistors 150B, four transistor elements 250C, a storage capacitor C1-B, and the micro light emitting diode 200A. Four transistor elements 251B to 254B and the micro light emitting diode 200A are transferred and bonded to multiple bonding areas such as a bonding area BA2-A and a bonding area BA3-A of the circuit substrate 100A after being manufactured elsewhere. Specifically, similar to the transistor element 251B and the micro light emitting diode 200A, the transistor element 252B, the transistor element 253B, and the transistor element 254B may also be simultaneously bonded onto the circuit substrate 100 during the transfer process. In other words, the transistor elements 252B to 254B may be formed on the same semiconductor substrate to form another transfer unit, but not limited thereto.

In the embodiment, a control terminal of transistor element 251B receives the gate drive signal SCAN1. A first terminal of transistor element 251B is coupled to a first terminal of thin film transistor 152B and receives the reset signal Vint. A second terminal of the transistor element 251B is coupled to a second terminal of the thin film transistor 151 and a first terminal (that is, a first electrode E1A terminal) of the micro light emitting diode 200A. A control terminal of the transistor element 252B is coupled to the transistor element 254B and receives the gate drive signal SCAN2. A first terminal of the transistor element 252B is coupled to a first terminal of the thin film transistor 151 and a second terminal of the transistor element 253B. A second terminal of the transistor element 252B is coupled a control terminal of the transistor element 253B, a second terminal of the thin film transistor 152B, and a first terminal of the storage capacitor C1-B. A first terminal of the transistor element 253B is coupled to a second terminal of the transistor element 254B and a second terminal of the thin film transistor 153. A first terminal of the transistor element 254B receives the image data Vdata. A second terminal (that is, a second electrode E2A terminal) of the micro light emitting diode 200A is coupled to the system low voltage VSS. A control terminal of the thin film transistor 151 is coupled to a control terminal of the thin film transistor 153 and receives the light emitting signal EM. A control terminal of the thin film transistor 152B receives the gate drive signal SCAN1. A first terminal of the thin film transistor 153 is coupled to a second terminal of the storage capacitor C1-B and the system high voltage VDD.

In the embodiment, the operation flow of the pixel circuit PC-B may be divided into three stages, which are respectively the reset stage, the data writing stage, and the light emitting stage. The transistor element 253B, the transistor element 254B, the thin film transistor 153, and the storage capacitor C1-B are a driving unit of the pixel circuit PC-B and are configured to write the image data Vdata into the storage capacitor C1-B during the data writing stage and control the driving current flowing through the micro light emitting diode 200A during the light emitting stage. The thin film transistor 151 is a light emission control unit of the pixel circuit PC-B and is configured to control the driving current from the driving unit to the micro light emitting diode 200A during the light emitting stage.

The transistor element 251B and the thin film transistor 152B are a reset unit of the pixel circuit PC-B and are configured to initialize the voltage of the first terminal of the storage capacitor C1-B of the driving unit during the reset stage. The transistor element 252B is a compensation unit of the pixel circuit PC-B and is configured to adjust the driving current flowing through the micro light emitting diode 200A during the light emitting stage. The driving unit is coupled between the reset unit and the light emission control unit, and the compensation unit is coupled between the light emission control unit and the driving unit.

Through the combined use of the thin film transistor 150B and the transistor element 250C, in addition to increasing the design margin of the pixel circuit PC-B, the operational electrical properties of the pixel circuit PC-B can also be improved, thereby increasing the reliability of the micro light emitting diode panel 10B. From another point of view, since the electrical properties of the two types of transistors are fairly different, the required process conditions are also different. Therefore, one type of the transistors is manufactured elsewhere and then transferred, which can increase the overall process flexibility. In other words, the overall production yield can be ensured while improving the operational electrical properties of the pixel circuit PC-B.

In summary, in the micro light emitting diode panel and the method of fabricating the same according to an embodiment of the disclosure, the circuit substrate for driving the micro light emitting diodes is provided with two types of transistors. The two types of transistors have significantly different electron mobility and are respectively the thin film transistor and the transistor element. The thin film transistor is formed during the process of manufacturing the circuit substrate, and the transistor element is transferred and bonded onto the circuit substrate after being manufactured elsewhere. Therefore, the process flexibility and the design margin of the micro light emitting diode panel can be increased. In addition, the configuration of the two types of transistors with completely different properties can also improve the operational electrical properties of the pixel circuit, thereby increasing the reliability of the micro light emitting diode panel.

What is claimed is:

1. A micro light emitting diode panel, comprising:
a circuit substrate, comprising:
a plurality of signal lines, composed of a plurality of metal conductive layers and defining a plurality of pixel areas;
a plurality of bonding pads, extending from at least part of the signal lines; and
a plurality of thin film transistors, formed on the circuit substrate, wherein each of the thin film transistors has a first semiconductor pattern and a plurality of electrodes composed of the metal conductive layers, and the electrodes are electrically connected to at least part of the bonding pads;
a plurality of transistor elements, electrically bonded to a part of the bonding pads and electrically connected to the thin film transistors; and
a plurality of micro light emitting diodes, electrically bonded to another part of the bonding pads and electrically connected to the thin film transistors, wherein each of the pixel areas is provided with at least one thin film transistor, at least one transistor element, and at least one micro light emitting diode, each of the transistor elements has a second semiconductor pattern, and an electron mobility difference between the first semiconductor pattern and the second semiconductor pattern is greater than 30 cm²/V·s.

2. The micro light emitting diode panel according to claim 1, further comprising:
a plurality of solder bumps, wherein the transistor elements and the micro light emitting diodes are electrically bonded to the circuit substrate via the solder bumps.

3. The micro light emitting diode panel according to claim 1, wherein the electrodes of each of the thin film transistors comprise a source, a drain, and a gate, the source and the drain are electrically connected to the first semiconductor pattern, the signal lines comprise a plurality of scan lines and a plurality of data lines, the source, the drain, and the data lines are a same film layer, and the gate and the scan lines are a same film layer.

4. The micro light emitting diode panel according to claim 3, wherein an electron mobility of the first semiconductor pattern of each of the thin film transistors is less than or equal to 20 cm²/V·s.

5. The micro light emitting diode panel according to claim 1, wherein each of the transistor elements further has a source, a drain, and a gate, and the source and the drain are electrically connected to the second semiconductor pattern, wherein the source, the drain, and the gate are located between the second semiconductor pattern and the circuit substrate, and an electron mobility of the second semiconductor pattern of each of the transistor elements is greater than 50 cm²/V·s.

6. The micro light emitting diode panel according to claim 1, wherein the circuit substrate has a plurality of pixel circuits disposed between the signal lines, and each of the pixel circuits comprises:
a driving unit, configured to control a driving current flowing through one of the micro light emitting diodes during a light emitting stage; and
a light emission control unit, configured to control the driving current from the driving unit to the one of the micro light emitting diodes during the light emitting stage, wherein the light emission control unit is provided with a first thin film transistor of the thin film transistors, and the driving unit is provided with a first transistor element of the transistor elements.

7. The micro light emitting diode panel according to claim 6, wherein each of the pixel circuits further comprises a reset unit configured to initialize a voltage of a first terminal of a storage capacitor of the driving unit connected to the reset unit during a reset stage, the driving unit is coupled between the reset unit and the light emission control unit, and the reset unit is provided with a second transistor element of the transistor elements.

8. The micro light emitting diode panel according to claim 7, wherein each of the pixel circuits further comprises a compensation unit coupled between the light emission control unit and the driving unit, and the compensation unit is configured to adjust the driving current flowing through the one of the micro light emitting diodes during the light emitting stage and is provided with a second thin film transistor of the thin film transistors.

9. The micro light emitting diode panel according to claim 8, wherein the compensation unit is further provided with a compensation capacitor connected to a control terminal of the second thin film transistor and a terminal of the second thin film transistor connected to the reset unit.

10. The micro light emitting diode panel according to claim 1, wherein at least one of the transistor elements and one of the micro light emitting diodes are disposed on a semiconductor substrate, and the at least one of the transistor elements and the one of the micro light emitting diodes are located between the semiconductor substrate and the circuit substrate.

11. A method of fabricating a micro light emitting diode panel, comprising:
manufacturing a plurality of signal lines, a plurality of thin film transistors, and a plurality of bonding pads on a first substrate to form a circuit substrate having a plurality of pixel circuits, wherein the thin film transistors are electrically connected to at least part of the bonding pads, and the bonding pads are electrically connected to a part of the signal lines;
forming a plurality of micro light emitting diodes on a second substrate;
forming a plurality of transistor elements on a third substrate or the second substrate, wherein each of the thin film transistors has a first semiconductor pattern, each of the transistor elements has a second semiconductor pattern, and an electron mobility difference between the first semiconductor pattern and the second semiconductor pattern is greater than 30 cm²/V·s;
transferring and bonding the micro light emitting diodes on the second substrate to a part of the bonding pads to electrically connect the thin film transistors of the circuit substrate; and
transferring and bonding the transistor elements on the third substrate or the second substrate to another part of the bonding pads to electrically connect the thin film transistors of the circuit substrate.

12. The method of fabricating the micro light emitting diode panel according to claim 11, wherein the second substrate is an epitaxial substrate.

13. The method of fabricating the micro light emitting diode panel according to claim 11, wherein the step of forming the micro light emitting diodes comprises:
forming a semiconductor material layer and an electrode layer on an epitaxial substrate;
transferring the semiconductor layer and the electrode layer from the epitaxial substrate to the second substrate, wherein the second substrate is a wafer substrate; and
performing an etching step on the semiconductor layer and the electrode layer to form the micro light emitting diodes.

14. The method of fabricating the micro light emitting diode panel according to claim 11, wherein the third substrate is a silicon-wafer substrate.

15. The method of fabricating the micro light emitting diode panel according to claim 11, wherein each of the pixel circuits comprises:
a driving unit, configured to control a driving current flowing through one of the micro light emitting diodes during a light emitting stage; and
a light emission control unit, configured to control the driving current from the driving unit to the one of the micro light emitting diodes during the light emitting stage, wherein the step of transferring and bonding the transistor elements comprises respectively transferring and bonding a plurality of first transistor elements to the driving unit of each of the pixel circuits.

16. The method of fabricating the micro light emitting diode panel according to claim 15, wherein the step of transferring and bonding the transistor elements further comprises respectively transferring and bonding a plurality of second transistor elements to a reset unit of each of the pixel circuits, wherein the reset unit is configured to initialize a voltage of a first terminal of a storage capacitor of the driving unit connected to the reset unit during a reset stage, and the driving unit is coupled between the reset unit and the light emission control unit.

17. The method of fabricating the micro light emitting diode panel according to claim 11, further comprising:
forming a semiconductor substrate on the second substrate, wherein the transistor elements and the micro light emitting diodes are formed in the semiconductor substrate, and the step of transferring and bonding the transistor elements and the micro light emitting diodes comprises transferring the semiconductor substrate.

18. The method of fabricating the micro light emitting diode panel according to claim 11, wherein each of the thin film transistors further has a source, a drain, and a gate, the source and the drain are electrically connected to the first semiconductor pattern, the signal lines comprise a plurality of scan lines and a plurality of data lines, the source, the drain, and the data lines are a same film layer, and the gate and the scan lines are a same film layer.

19. The method of fabricating the micro light emitting diode panel according to claim 11, wherein an electron mobility of the first semiconductor pattern of each of the thin film transistors is less than or equal to 20 cm²/V·s.

20. The method of fabricating the micro light emitting diode panel according to claim 11, wherein each of the transistor elements further has a source, a drain, and a gate, and the source and the drain are electrically connected to the second semiconductor pattern, wherein the source, the drain, and the gate are located between the second semiconductor pattern and the circuit substrate, and an electron mobility of the second semiconductor pattern is greater than 50 cm²/V·s.
